(19) United States
(12) Patent Application Publication
(10) Pub. No.: US 2024/0157563 A1
(43) Pub. Date: May 16, 2024

(54) SUBSTRATE CONVEYANCE ROBOT AND SUBSTRATE EXTRACTION METHOD

(71) Applicant: KAWASAKI JUKOGYO KABUSHIKI KAISHA, Kobe-shi, Hyogo (JP)

(72) Inventors: Satoshi HASHIZAKI, Kobe-shi (JP); Shinya KITANO, Kobe-shi (JP)

(73) Assignee: KAWASAKI JUKOGYO KABUSHIKI KAISHA, Kobe-shi, Hyogo (JP)

(21) Appl. No.: 18/282,870

(22) PCT Filed: Mar. 16, 2022
(86) PCT No.: PCT/JP2022/011773

§ 371 Date: Sep. 19, 2023

(30) Foreign Application Priority Data
Mar. 19, 2021 (JP) 2021-045514

(51) Int. Cl. B25J 9/16; B25J 11/00; B25J 13/08; G06T 7/593; G06T 7/73

(52) U.S. Cl. CPC B25J 9/1697; B25J 11/0095; B25J 13/08; G06T 7/593; G06T 7/74; G06T 2207/10012; G06T 2207/30148

(57) ABSTRACT

A robot includes an arm, a hand, a camera, a calculation unit, and a motion controller. The hand is attached to the arm, and supports and transfers a substrate. The camera is attached to the hand and captures images of the substrate disposed at the take-out position from a plurality of viewpoints to acquire images of the substrate. The calculator calculates three-dimensional information of the substrate based on the hand acquired by the camera. The motion controller moves the hand to take out the substrate based on the three-dimensional information of the substrate calculated by the calculator.

### TECHNICAL FIELD

This invention mainly relates to a substrate (wafer) transfer robot that transfers a substrate.

### BACKGROUND ART

Conventionally, substrate transfer robots are known to transfer substrates for manufacturing semiconductor devices. Substrate transfer robots are generally horizontal articulated robots including a plurality of arms and a hand that rotate in a vertical direction around a rotational axis.

PTL 1 discloses a vertical articulated arm robot. A work tool and a camera are attached to an end of an arm. The work tool is a robot hand or a welding tool, which performs work on an object. The camera captures an image of the object. PTL 1 discloses that a three-dimensional position of the object is calculated based on a plurality of images obtained by the camera.

### PRIOR-ART DOCUMENTS

### Patent Documents

PTL 1: Japanese Patent Application Laid-Open 2010-117223.

### SUMMARY OF THE INVENTION

### Problems to be Solved by the Invention

A substrate transfer robot operates an arm and a hand based on pre-taught information to take out and transfer a substrate placed at a take-out position. However, if the substrate is misaligned with a predetermined position or if a substrate shape has changed, as typified by substrate warpage, there is a possibility that the substrate transfer robot will not properly take out the substrate. In this regard, PTL 1 does not disclose a horizontally articulated robot and substrate removal.

The present invention is made in view of the above circumstances, and the main purpose is to provide a substrate transfer robot that properly takes out and transfers a substrate based on three-dimensional information of the substrate.

### Means for Solving the Problems

The problem to be solved by the present invention is as described above, and the means for solving this problem and effects are described below.

According to a first aspect of the present invention, a substrate transfer robot having the following configuration is provided. That is, the substrate transfer robot is a horizontal articulated type and transfers a substrate. The substrate transfer robot includes an arm, a hand, a camera, a calculator, and a motion controller. The hand is attached to the arm, and supports and transfers the substrate. The camera is attached to the hand and captures images of the substrate placed at a take-out position from a plurality of viewpoints to acquire images of the substrate. The calculator calculates three-dimensional information of the substrate based on the images acquired by the camera. The motion controller moves the hand to take out the substrate based on the three-dimensional information of the substrate calculated by the calculator.

According to a second aspect of the present invention, the following substrate take-out method is provided. That is, in the substrate take-out method, a substrate placed at a take-out position is taken out using a horizontally articulated robot. The substrate take-out method includes a photographing process, a calculation process, and a take-out process. In the photographing process, a camera attached to a hand included in the robot is used to capture images of the substrate placed at a take-out position from a plurality of viewpoints to acquire images of the substrate. In the calculation process, three-dimensional information of the substrate is calculated based on the images acquired in the photographing process. In the take-out process, the hand is moved to take out the substrate based on the three-dimensional information of the substrate calculated in the calculation process.

This allows the actual position or shape of the substrate to be recognized by calculating the three-dimensional information of the substrate, and the substrate can be taken out.

### Effects of the Invention

According to the present invention, a substrate can be properly taken out and transported based on three-dimensional information of the substrate.

### BRIEF DESCRIPTION OF THE DRAWINGS

FIG. 1 is a perspective diagram of a robot of a first embodiment.

FIG. 2 is a block diagram of the robot.

FIG. 3 is a flowchart showing the process performed by a controller when a substrate take-out operation is performed.

FIG. 4 shows how a camera provided on a hand captures images of the substrate and the captured images.

FIG. 5 shows a side view of how the camera provided on the hand captures images of the substrate.

FIG. 6 is a plan view of a robot of a second embodiment.

### EMBODIMENT FOR CARRYING OUT THE INVENTION

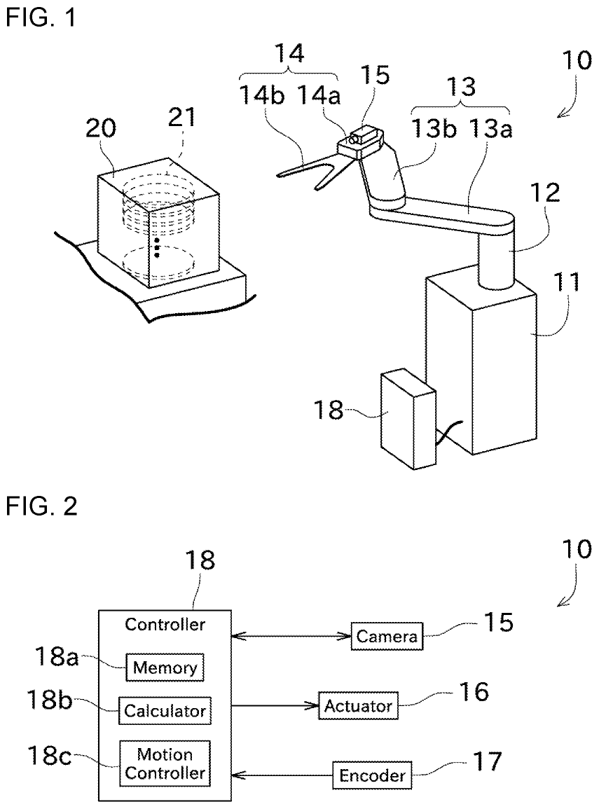

Next, the embodiments of the invention will be described with reference to the drawings. FIG. 1 is a perspective diagram of the overall configuration of a robot (substrate transfer robot) 10 of a first embodiment. FIG. 2 is a block diagram of the robot 10.

The robot 10 is a SCARA (Selective Compliance Assembly Robot Arm) type horizontal articulated robot. SCARA is an abbreviation for Selective Compliance Assembly Robot Arm. The robot 10 is installed in a factory where substrates are manufactured or processed, and performs work of transporting a substrate 21 between multiple positions. An environment in which the robot 10 is installed is a clean and vacuum environment.

The robot 10 includes a base 11, an elevation shaft 12, an arm 13, a hand 14, a camera 15, and a controller 18.

The base 11 is fixed to a floor of the factory or the like. However, this is not limited to this, and the base 11 may be fixed to a suitable processing facility or ceiling surface, for example.

The elevation shaft 12 connects the base 11 and the arm 13. The elevation shaft 12 is movable in a vertical direction with respect to the base 11. The height of arm 13 and hand 14 can be changed by elevating and lowering the elevation shaft 12.

The arm 13 includes a first arm 13a and a second arm 13b. The first arm 13a is an elongated member that extends in a straight horizontal direction. One end of the first arm 13a in a longitudinal direction is attached to an upper end of the elevation shaft 12. The first arm 13a is rotatably supported around an axis (vertical axis) of the elevation shaft 12. A second arm 13b is attached to the other end of the first arm 13a in the longitudinal direction. The second arm 13b is an elongated member that extends in a straight horizontal direction. One end of the second arm 13b in a longitudinal direction is attached to the end of the first arm 13a. The second arm 13b is rotatably supported around an axis (vertical axis) parallel to the elevation shaft 12. The hand 14 is attached to the other end of the second arm 13b in the longitudinal direction. The configuration of the arm 13 is not limited to the configuration of the present embodiment.

The hand 14 is a so-called passive grip type, and places and transports the substrate 21. The hand 14 includes a base 14a and a tip 14b.

The base 14a is attached to an end of the second arm 13b. The base 14a is rotatable around an axis (vertical axis) parallel to the elevation shaft 12. The tip 14b is attached to an end of the base 14a. The tip 14b is a substantially U-shaped thin plate member including a branched structure. The tip 14b rotates integrally with the base 14a. The substrate 21 is placed on the tip 14b. The base 14a and the tip 14b may be formed integrally.

The hand 14 is not limited to a passive grip type. The hand 14 may be an edge grip type or a suction type. Regarding the passive grip type, the substrate 21 placed on the hand 14 is not fixed, but regarding the edge grip type, an edge of the substrate 21 placed on the hand 14 is clamped and fixed. The suction type has a configuration in which the substrate 21 is suctioned and transported under negative pressure (e.g., Bernoulli chuck). In any configuration, the hand supports the substrate 21 and transports the substrate 21. Two hands 14 may be provided with the arm 13.

The elevation shaft 12, the first arm 13a, the second arm 13b, and the base 14a are each driven by an actuator 16 shown in the block diagram of FIG. 2. Although only one actuator 16 is shown in FIG. 2, the actuator 16 is provided for each moving part actually.

Arm joints located between the elevation shaft 12 and the first arm 13a, between the first arm 13a and the second arm 13b, and between the second arm 13b and the base 14a are provided with encoders 17 that detect a rotational position of the respective members. At appropriate locations in the robot 10, encoders 17 are also provided to detect changes in the position of the first arm 13a in a height direction (i.e., the amount of elevation of the elevation shaft 12). Although only one encoder 17 is shown in FIG. 2, an encoder 17 is actually provided for each joint.

The camera 15 is provided on a top surface of the hand 14, more particularly on the top surface of the base 14a. The camera 15 is fixed to rotate integrally with the hand 14 (not rotating relative to the hand 14). An optical axis of the camera 15 is directed toward the tip side of the hand 14. The optical axis of the camera 15 indicates a direction in which the camera 15 acquires an image, specifically, a straight line parallel to the axial direction of the camera 15 through an imager of the camera 15. The camera 15 is a monocular camera, not a stereo camera. Therefore, the camera 15 creates a single image by using one imager to capture from a single viewpoint. The viewpoint is a position and orientation of the camera 15 (imager) when capturing an object.

The camera 15 acquires an image by capturing a plurality of substrates 21 that are accommodated in an opening/closing container (accommodating body) 20. The container 20 is, for example, a FOUP (Front Opening Unified Pod). The plurality of substrates 21 are arranged alongside in a thickness direction in the container 20. The number of substrates 21 that can be accommodated is not particularly limited, but is, for example, in the range of 10-40 substrates, and generally a container 20 that can accommodate 25 substrates 21 is often used. Instead of the container 20, another accommodating body, for example, an opening/closing shelf for storing the substrates 21, may be used. Since the robot 10 in the present embodiment takes out the substrate 21 accommodated in the container 20, the accommodating position of the container 20 corresponds to the take-out position.

In the present embodiment, the base 14a is located higher than the tip 14b, so that the tip 14b is less visible in the image. The height of the base 14a and the tip 14b may be the same. The camera 15 may be provided on the base 14a. In the present embodiment, the camera 15 (imager) is located on the extension of the line segment connecting the center of rotation of the base 14a and the center of the tip 14b (the center position of the substrate 21 when the substrate 21 is placed on it) in plan view. However, the camera 15 may be positioned off this extension line.

The controller 18 includes a memory 18a, such as an HDD, an SSD, or a flash memory, and an arithmetic unit, such as a CPU. The computing device functions as a calculator 18b and an operation controller 18c by executing a program stored in the memory 18a. The calculator 18b performs processing to calculate three-dimensional position and three-dimensional shape of the substrate 21 based on the images acquired by the camera 15 (details are described below). The motion controller 18c controls the motion of the elevation shaft 12, the first arm 13a, the second arm 13b, and the hand 14 based on the height of the lifting axis 12, the rotational position of the first arm 13a, the rotational position of the second arm 13b, and the rotational position of the hand 14 detected by the encoder 17.

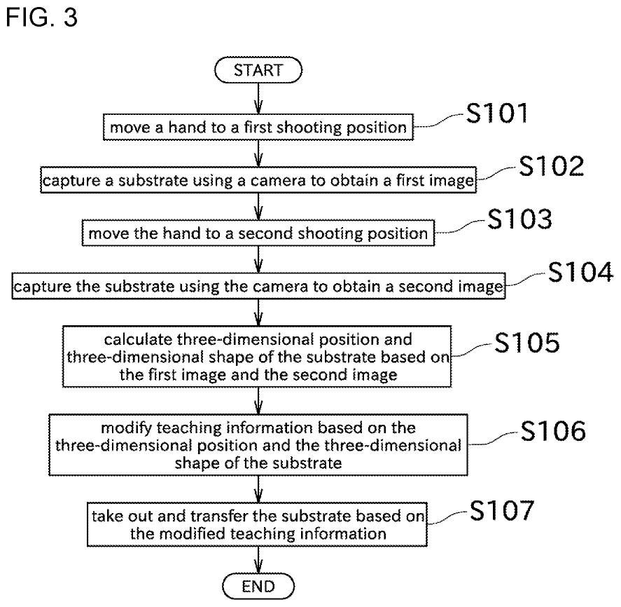

Next, with reference to FIG. 3-FIG. 5, the process in which the robot 10 takes out and transports the substrate 21 accommodated in the container 20 (substrate take-out method) will be described.

In the present method, initially, the camera 15 provided with the robot 10 is used to capture the image of the substrate 21 accommodated in the container 20. Then, based on the image of the substrate 21, the three-dimensional position and three-dimensional shape of the substrate 21 are calculated, and based on the three-dimensional position and three-dimensional shape of the substrate 21, the robot 10 is operated to take out the substrate 21. The following is a specific description.

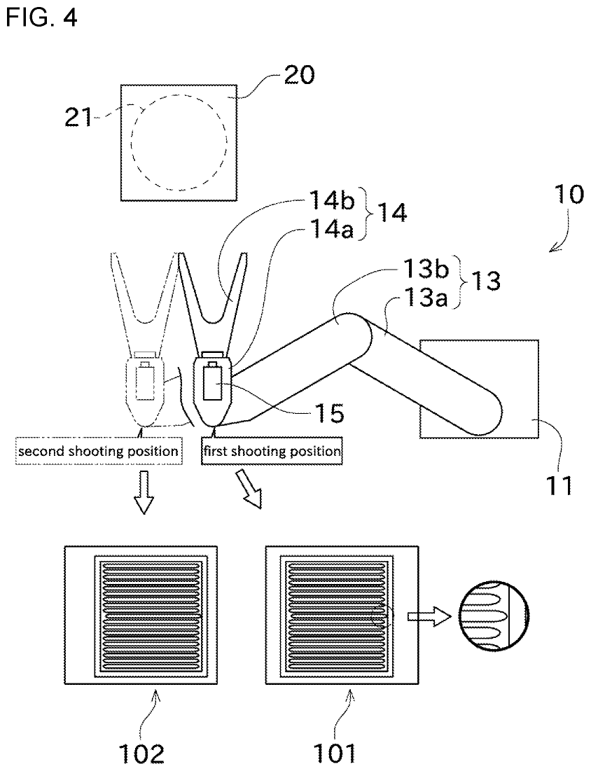

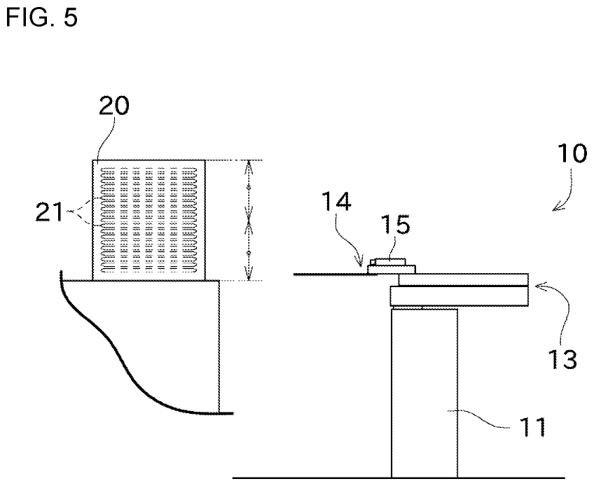

First, the controller 18 (motion controller 18c) moves the hand 14 to a first shooting position (S101). A horizontal position of the first shooting position is a position facing the opening surface of the container 20, as shown in FIG. 4. The height of the first shooting position is the height at which the camera 15 is located below the midpoint of a height direction of the container 20 (in other words, the midpoint of the line segment connecting the uppermost substrate 21 and the lowest substrate 21), as shown in FIG. 5. By disposing the camera 15 at a relatively low position, the hand 14 is less likely to get in the way of photographing the substrates 21, so that more substrates 21 can be captured in a single image.

Next, the controller 18 captures the substrate 21 using the camera 15 to obtain a first image 101 (S102, capturing process). The first image 101 is an image acquired by capturing with the camera 15 when the hand 14 is located at the first shooting position. As shown in FIG. 5, the first image 101 includes all the substrates 21 accommodated in the container 20. The first image 101 may include only some of the substrates 21 accommodated in the container 20.

Next, the controller 18 (operation controller 18c) moves the hand 14 to a second shooting position (S103). A horizontal position of the second shooting position is a position facing the opening surface of the container 20, as shown in FIG. 4. In the present embodiment, the distance from the container 20 to the first shooting position and the distance from the container 20 to the second shooting position are the same, but may be different. The height of the second shooting position is the height at which the camera 15 is located below the midpoint of the container 20 in a height direction, as shown in FIG. 5. In the present embodiment, the height of the second shooting position is the same as the height of the first embodiment, but may be different.

Next, the controller 18 captures the substrate 21 using the camera 15 to obtain a second image 102 (S104, capturing process). The second image 102 is the image acquired by capturing with the camera 15 when the hand 14 is located at the second shooting position. As shown in FIG. 5, the second image 102 includes all the substrates 21 accommodated in the container 20. The second image 102 may include only some of the substrates 21 accommodated in the container 20.

Next, the controller 18 (calculator 18b) calculates the three-dimensional position and the three-dimensional shape of the substrate 21 based on the first image and the second image (S105, calculation process). Specifically, the controller 18 performs a known stereo matching process on the first image and the second image to calculate the misalignment (parallax) of the corresponding positions of the first image and the second image. The controller 18 calculates the three-dimensional position of a target pixel (object) based on the calculated parallax, the first shooting position (position of the camera 15 in detail), and the second shooting position (position of the camera 15 in detail). The first shooting position and the second shooting position are known values because they are predetermined and stored in the memory 18a. In particular, the horizontally articulated robot that transports the substrate 21 can stop at the first shooting position and the second shooting position with high accuracy because the robot is capable of precise position control.

By performing the above processing, the three-dimensional position of each pixel comprising the substrate 21 can be calculated. As a result, the three-dimensional information of the substrate 21 can be calculated. The three-dimensional information is information that includes at least one of the three-dimensional position and the three-dimensional shape. The three-dimensional position of the substrate 21 is the three-dimensional position (coordinate value) of a reference point (arbitrary position, for example, center) of the substrate 21. The three-dimensional shape of the substrate 21 is the shape created by aligning the three-dimensional position of the surface of the relevant substrate 21.

In the present embodiment, the first image and the second image include all the substrates 21 accommodated in the container 20. Therefore, in the processing of step S105, the three-dimensional position and the three-dimensional shape are calculated for all the substrates 21 accommodated in the container 20.

Next, the controller 18 modifies teaching information based on the three-dimensional position and the three-dimensional shape of the substrate 21 (S106). The teaching information is information that defines the position and sequence to operate the robot 10. The controller 18 operates the elevation shaft 12, the arm 13, and the hand 14 in accordance with the teaching information, so that the substrates 21 accommodated in the container 20 can be taken out in sequence and transported to a predetermined position. Here, the teaching information created in advance assumes that the substrate 21 is in an ideal position. The substrate 21 being the ideal position means, for example, that the center of the support position of the container 20 and the center of the substrate 21 are coincident. Furthermore, the teaching information assumes that the substrate 21 has a standard shape. However, in reality, due to heat treatment or other circumstances, the substrate 21 may not have a standard shape (for example, it may be warped).

Therefore, the controller 18 modifies the teaching information based on the three-dimensional position and the three-dimensional shape of the respective substrate 21 calculated in step S105. For example, as shown in FIG. 4, if the actual position of a certain substrate 21 is misaligned by n mm in a first direction (right direction in FIG. 4), the position that the teaching information detects is also increased by n mm in the first direction. If there is a warp in a certain substrate 21, the teaching information is changed so that the hand 14 does not collide with the warping point. From another perspective, the controller 18 modifies the teaching information so that the reference position of the hand 14 (e.g., center) and the reference position of the substrate 21 (e.g., center and bottom) coincide.

In the present embodiment, the teaching information created in advance is modified. Alternatively, the teaching information may be newly created based on the three-dimensional position and the three-dimensional shape of the substrate 21 created in step S105 without calculating the teaching information in advance.

Thereafter, the controller 18 (motion controller 18c) controls the elevation shaft 12, the arm 13, and the hand 14 to take out and transport the substrate 21 based on the teaching information modified in step S106 (take-out process, S107).

By performing the above processing, the substrate 21 can be properly taken out even if the three-dimensional position or the three-dimensional shape of the substrate 21 is different from the teaching position. Only the three-dimensional position of the substrate 21 may be calculated without calculating the three-dimensional shape of the substrate 21, and the teaching information may be modified or created based only on the three-dimensional position. Alternatively, only the three-dimensional shape of the substrate 21 may be calculated without calculating the three-dimensional position of the substrate 21, and the teaching information may be modified or created based only on the three-dimensional shape.

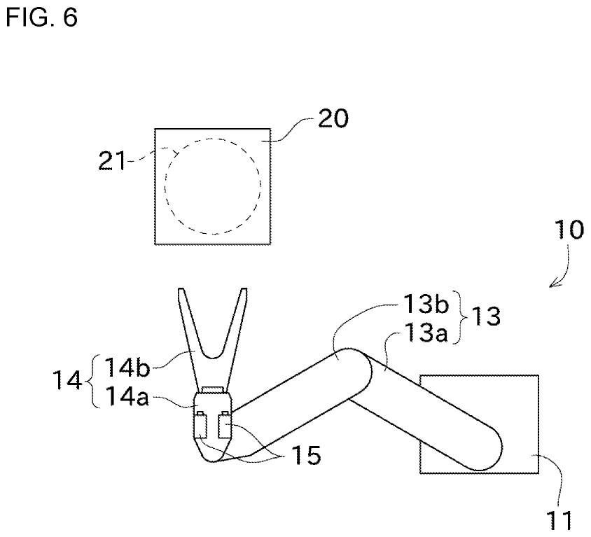

Next, a second embodiment is described with reference to FIG. 6. In the above embodiment, the hand 14 is moved to capture two images for calculation of the three-dimensional position information by capturing the substrate 21 at the first shooting position and the second shooting position. This configuration enables low-cost implementation, since only one camera 15 is needed and there is no need to use a stereo camera or two cameras 15.

In contrast, in the second embodiment, two cameras 15 are placed on the hand 14, as shown in FIG. 6. In this case, two images for calculation of the three-dimensional information can be obtained by simply capturing the substrate 21 at one shooting position. In the second embodiment, since only one shooting position is required, the time required for processing to calculate the three-dimensional information of the substrate 21 can be reduced. Instead of a configuration with two cameras 15, a stereo camera (a camera with a configuration in which two imager are provided in one housing) may be used.

As explained above, the robot 10 of the present embodiment is the horizontally articulated robot for that transports substrates 21. The robot 10 includes the arm 13, the hand 14, the camera 15, the calculator 18b, and the motion controller 18c. The hand 14 is attached to the arm 13, and supports and transports the substrate 21. The camera 15 is attached to the hand 14 and captures images of the substrate 21 placed at the take-out position from the plurality of viewpoints to acquire images of the substrate 21 (capturing process). The calculator 18b calculates the three-dimensional information of the substrate 21 based on the hand 14 acquired by the camera 15 (calculation process). The motion controller 18c moves the hand 14 to take-out the substrate 21 based on the three-dimensional information of the substrate 21 calculated by the calculator 18b (take-out process).

This allows the actual position or the actual shape of the substrate 21 to be recognized by calculating the three-dimensional information of the substrate 21, and thus the substrate 21 can be taken out.

In the robot 10 of the present embodiment, the plurality of substrates 21 are placed at the take-out position. The camera 15 acquires images containing the plurality of substrates 21 from the plurality of viewpoints. The calculator 18b calculates the three-dimensional information of the plurality of substrates 21 based on the images obtained by the camera 15.

This allows the three-dimensional information of the plurality of substrates 21 to be calculated more efficiently compared to the process of calculating the three-dimensional information of the substrates 21 one by one.

In the robot 10 of the present embodiment, the substrates 21 are accommodated in the container 20 that can accommodate the plurality of substrates 21. The camera 15 acquires an image that includes all the substrates 21 accommodated in one container 20. The calculator 18b calculates the three-dimensional information of all the substrates 21 accommodated in the container 20 based on the images obtained by the camera 15.

This allows the process of taking out the substrates 21 accommodated in the container 20 to be performed efficiently.

In the robot 10 of the present embodiment, the calculator 18b calculates the three-dimensional information of all the substrates 21 accommodated in one container 20 based on the two images obtained by the camera 15.

This allows the three-dimensional information of the plurality of substrates 21 to be calculated more efficiently compared to a configuration of the same processing in which three or more images are acquired.

In the robot 10 of the present embodiment, the camera 15 is disposed on the top surface of the hand 14, and the camera 15 captures an image of the substrates 21 from a position lower than the center of the container 20 in the height direction.

This allows the hand 14 to be less likely to get in the way when capturing the substrate 21.

In the robot 10 of the present embodiment, the motion controller 18c moves the hand 14 to align the reference position of the substrate 21 with the reference position of the hand 14 to take out the substrate 21.

This allows the substrate 21 to be properly taken out.

In the robot 10 of the present embodiment, the calculator 18b calculates the three-dimensional position and the three-dimensional shape of the substrate 21. The motion controller 18c moves the hand 14 to take out the substrate 21 based on the three-dimensional position and the three-dimensional shape of the substrate 21 calculated by the calculator 18b.

This allows the substrate 21 to be properly taken out even when the substrate 21 is not a standard shape.

In the robot 10 of the present embodiment, the camera 15 is a monocular camera with a single imager. One monocular camera is disposed on the hand 14. The motion controller 18c acquires images of the substrate 21 from the plurality of viewpoints by positioning the hand 14 in the first shooting position and capturing the substrate 21, and then positioning the hand 14 in the second shooting position and capturing the substrate 21.

This allows images of the substrate 21 from the plurality of viewpoints to be acquired without disposing two cameras 15 or using a stereo camera.

While suitable embodiments of the present invention have been described above, the above configuration can be modified, for example, as follows.

In the above embodiment, the three-dimensional position and the three-dimensional shape are calculated by acquiring images of the substrate 21 accommodated in the container 20. Alternatively, the three-dimensional position and the three-dimensional shape may be calculated by acquiring an image for a substrate 21 that is not accommodated in the container 20 (for example, a substrate 21 that is placed on a workbench).

In the above embodiment, the first image 101 and the second image 102 are used to calculate the three-dimensional position and the three-dimensional shape of all the substrates 21 accommodated in the container 20. Alternatively, three or more images may be used to calculate the three-dimensional position and the three-dimensional shape of all the substrates 21 accommodated in the container 20. This allows for cases where it is difficult to acquire images including all the substrates 21 accommodated in the container 20.

The flowchart shown in the above embodiment is an example, and some processes may be omitted, the contents of some processes may be changed, or new processes may be added. For example, in the above embodiment, the teaching information of all the substrates 21 accommodated in the substrate 21 is modified at the beginning, and then the taking-out of the substrate 21 is started. In contrast, the teaching information of the substrates 21 may be modified one by one. Specifically, the image of one of the substrates 21 to be taken out is acquired, the teaching information is modified, so that the corresponding substrate 21 is taken out. The same process is performed for the subsequent substrate 21.

The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. In the present disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

1. A horizontally articulated substrate transfer robot that transfers a substrate comprising:
an arm;
a hand attached to the arm that supports and transfers the substrate;
a camera attached to the hand that captures images of the substrate placed at a take-out position from a plurality of viewpoints to acquire images of the substrate;
a calculator that calculates three-dimensional information of the substrate based on the images acquired by the camera; and
a motion controller that moves the hand to take out the substrate based on the three-dimensional information of the substrate calculated by the calculator.

2. The substrate transfer robot according to claim 1, wherein a plurality of the substrates are disposed at the take-out position, the camera acquires images that include the plurality of the substrates from the plurality of viewpoints, and
the calculator calculates three-dimensional information of the plurality of the substrates based on the images obtained by the camera.

3. The substrate transfer robot according to claim 2, wherein the substrate is accommodated in an accommodating body that can accommodate the plurality of the substrates,
the camera acquires an image that includes all the substrates accommodated in the accommodating body, and
the calculator calculates three-dimensional information of all the substrates accommodated in the accommodating body based on the image obtained by the camera.

4. The substrate transfer robot according to claim 3, wherein the calculator calculates three-dimensional information of all the substrates accommodated in the accommodating body based on two images obtained by the camera.

5. The substrate transfer robot according to claim 3, wherein
the camera is disposed on a top surface of the hand, and the camera captures an image of the substrate from a position lower than the center of the accommodating body in a height direction.

6. The substrate transfer robot of claim 1, wherein
the motion controller moves the hand to align a reference position of the substrate with a reference position of the hand to take out the substrate.

7. The substrate transfer robot of claim 1, wherein
the motion controller moves the hand to take out the substrate based on a three-dimensional position and a three-dimensional shape of the substrate calculated by the calculator.

8. The substrate transfer robot of claim 1, wherein
the camera is a monocular camera with a single imager,
the monocular camera is disposed on the hand, and
the motion controller acquires images of the substrate from the plurality of viewpoints by positioning the hand in a first shooting position and capturing the substrate, and then positioning the hand in a second shooting position and capturing the substrate.

9. A substrate take-out method of taking out a substrate placed at a take-out position using a horizontally articulated robot comprising:
a photographing process in which a camera attached to a hand included in the robot is used to capture images of the substrate placed at a take-out position from a plurality of viewpoints to acquire images of the substrate;
a calculation process in which three-dimensional information of the substrate is calculated based on the images acquired in the photographing process; and
a take-out process in which the hand is moved to take out the substrate based on the three-dimensional information of the substrate calculated in the calculation process.
